(19) United States
(12) Patent Application Publication
(10) Pub. No.: US 2014/0016293 A1
(43) Pub. Date: Jan. 16, 2014

(54) HIGH FREQUENCY MODULE HAVING SURFACE ACOUSTIC WAVE DEVICE AND METHOD FOR MANUFACTURING THE SAME

(71) Applicant: In Ho SONG, Osan-si (KR)

(72) Inventor: In Ho SONG, Osan-si (KR)

(73) Assignee: WISOL CO., LTD., Osan-si (KR)

(21) Appl. No.: 13/549,132

(22) Filed: Jul. 13, 2012

(51) Int. Cl. H05K 9/00; H05K 3/00

(52) U.S. Cl. 361/818; 29/829

(57) ABSTRACT

A high frequency module having a surface acoustic wave device and a method of manufacturing the same are provided. The high frequency module includes a substrate provided with a top ground pattern at both upper ends and provided with, inside thereof, an inner ground pattern electrically connected to the top ground pattern through a via electrode; at least one SAW device installed on the substrate; a molding layer formed on the substrate to cover the SAW device and provided with a groove at both ends to expose the top ground pattern; and an electromagnetic wave shield layer formed to cover a surface of the molding layer including an inside of the groove.

### BACKGROUND OF TUE INVENTION

1. Field of the Invention

The present invention relates to a high frequency module having a surface acoustic wave device and a method of manufacturing the same, and more specifically, to a high frequency module having a surface acoustic wave device and a method of manufacturing the same, in which a ground pattern provided on a substrate is electrically connected to an electromagnetic wave shield layer formed on a molding layer, and thus electromagnetic wave shield performance is improved.

2. Background of the Related Art

As the communication industry advances, wireless communication products gradually have a tendency of miniaturization, high quality and multi-functionality. To keep pace with such a tendency, components used in the wireless communication products, e.g., filters, duplexers and the like, are required to be miniaturized and multi-functionalized. As an example of such a product, a surface acoustic wave (SAW) device is used.

The surface acoustic wave device is a device which transforms electrical signals and surface acoustic waves using a comb-shaped electrode (inter digital transducer, IDT) configured of a thin film metal installed on a piezoelectric substrate and transmits and receives signals.

Since such a surface acoustic wave device has features such as compactness, lightweightness, high reliability, excellent out of band attenuation characteristics and the like, it is widely used as a frequency filter, a resonator or the like in the field of video device or mobile communication device.

Accordingly, development of a high frequency module capable of effectively preventing inflow and outflow of noise signals, while having excellent capability of shielding electromagnetic waves, is continuously requested recently. An example thereof is a high frequency module for GPS.

### SUMMARY OF THE INVENTION

Therefore, the present invention has been made in view of the above problems, and it is an object of the present invention to provide a high frequency module having a surface acoustic wave device and a method of manufacturing the same, in which a ground pattern provided on a substrate is electrically connected to an electromagnetic wave shield layer formed on a molding layer, and thus electromagnetic wave shield performance is improved.

To accomplish the above object, according to one aspect of the present invention, there is provided a high frequency module having a surface acoustic wave device, the module including: a substrate provided with a top ground pattern at both upper ends and provided with, inside thereof, an inner ground pattern electrically connected to the top ground pattern through a via electrode; at least one SAW device installed on the substrate; a molding layer formed on the substrate to cover the SAW device and provided with a groove at both ends to expose the top ground pattern; and an electromagnetic wave shield layer formed to cover a surface of the molding layer including an inside of the groove.

Here, the groove may be formed to be extended downward into the substrate and expose the top ground pattern.

In addition, the groove may be formed to be extended to a bottom surface of the substrate and expose both side surfaces of the substrate including the inner ground pattern.

In addition, the SAW device may include at least any one of a SAW filter and a SAW duplexer.

In addition, the electromagnetic wave shield layer may be formed of a material including at least any one of Ag and Cu.

In addition, the electromagnetic wave shield layer may be formed in at least any one of methods including a plating method, a spray method and a sputter method.

In addition, to accomplish the above object, according to another aspect of the present invention, there is provided a method of manufacturing a high frequency module having a surface acoustic wave device, the method including the steps of: preparing a substrate provided with a top ground pattern at both upper ends and provided with, inside thereof, an inner ground pattern electrically connected to the top ground pattern through a via electrode; installing one or more SAW devices on a top surface of the substrate; forming a molding layer on the substrate to cover the SAW device; forming a groove by removing a portion of the molding layer between the SAW devices to expose the top ground pattern; forming an electromagnetic wave shield layer on a surface of the molding layer including an inside of the groove; and dividing the high frequency module into individual high frequency module units by cutting the high frequency module along a dicing line.

In addition, to accomplish the above object, according to still another aspect of the present invention, there is provided a method of manufacturing a high frequency module having a surface acoustic wave device, the method including the steps of: preparing a substrate provided with a top ground pattern at both upper ends and provided with, inside thereof, an inner ground pattern electrically connected to the top ground pattern through a via electrode; installing one or more SAW devices on a top surface of the substrate; forming a molding layer on the substrate to cover the SAW device; forming a groove by removing a portion of the molding layer and the substrate between the SAW devices to expose the top ground pattern and the inner ground pattern; forming an electromagnetic wave shield layer on a surface of the molding layer including an inside of the groove; and dividing the high frequency module into individual high frequency module units by cutting the high frequency module along a dicing line.

Here, in the step of forming a groove by removing a portion of the molding layer and the substrate between the SAW devices to expose the top ground pattern and the inner ground pattern, the substrate may be removed as much as some of thickness or entire thickness.

In addition, the dicing line passes through a center of the groove.

### BRIEF DESCRIPTION OF THE DRAWINGS

FIG. 1 is a cross-sectional view showing the structure of a high frequency module having a surface acoustic wave device according to a first embodiment of the present invention.

FIG. 2 is a cross-sectional view showing the structure of a high frequency module having a surface acoustic wave device according to a second embodiment of the present invention.

FIG. 3 is a cross-sectional view showing the structure of a high frequency module having a surface acoustic wave device according to a third embodiment of the present invention.

FIGS. 4A to 4G are cross-sectional views sequentially illustrating a method of manufacturing a high frequency module having a surface acoustic wave device according to a first embodiment of the present invention.

FIGS. 5A to 5G are cross-sectional views sequentially illustrating a method of manufacturing a high frequency module having a surface acoustic wave device according to a second embodiment of the present invention.

FIGS. 6A to 6E are cross-sectional views sequentially illustrating a method of manufacturing a high frequency module having a surface acoustic wave device according to a third embodiment of the present invention.

### DETAILED DESCRIPTION OF THE PREFERRED EMBODIMENT

Hereafter, the preferred embodiments of the invention will describe a high frequency module having a surface acoustic wave device and a method of manufacturing the same in detail with reference to the accompanying drawings. The embodiments described below are provided as examples to sufficiently transfer the spirits of the invention to those skilled in the art. Accordingly, the present invention is not limited to those embodiments described below and can be embodied in different forms. In addition, in the drawings, the size and the thickness of an apparatus could be exaggerated for convenience. Throughout the disclosure, like reference numerals refer to like parts throughout the various figures and embodiments of the present invention.

First, a high frequency module having a surface acoustic wave device according to a first embodiment of the present invention will be described in detail with reference to FIG. 1.

FIG. 1 is a cross-sectional view showing the structure of a high frequency module having a surface acoustic wave device according to a first embodiment of the present invention.

As shown in FIG. 1, the high frequency module having a surface acoustic wave device according to the first embodiment of the present invention largely includes a substrate 10, at least one surface acoustic wave (hereinafter, referred to as SAW) device 20 installed on the substrate 10, a molding layer 30 formed on the substrate 10 to cover the SAW device 20, and an electromagnetic wave shield layer 40 formed on the surface of the molding layer 30.

The substrate 10 may be formed of a multi-layer substrate such as a ceramic substrate or a PCB substrate.

A top ground pattern 11 is provided at both upper ends of the substrate 10. The top surface of the top ground pattern 11 is exposed to outside of the substrate 10.

In addition, an inner ground pattern 13 electrically connected to the top ground pattern 11 through a via electrode 12 formed to pass through a portion of the substrate 10 is provided inside the substrate 10.

That is, the top ground pattern 11 and the inner ground pattern 13 are provided in different layers, and they are electrically connected to each other through the via electrode 12 formed to pass through a portion of the substrate 10.

At this point, although it is shown in the figure that two inner ground patterns 13 are provided in different layers inside the substrate 10, the number of the inner ground patterns 13 is not limited thereto.

An electrode pattern 21 is provided on the top surface of the substrate 10, and the SAW device 20 is installed on the electrode pattern 21.

The SAW device 20 may include at least any one of a SAW filter and a SAW duplexer.

That is, although it is shown in FIG. 1 that one SAW device 20, e.g., one SAW filter or one SAW duplexer, is installed on the substrate 10, both of the SAW filter and the SAW duplexer may be installed on the substrate 20 as the SAW device 20.

After an inter digital transducer (IDT) electrode is formed on the surface of a piezoelectric substrate, the SAW filter uses a principle of transforming an electrical signal applied to the IDT electrode into mechanical energy of a piezoelectric material by a piezoelectric effect, and the SAW filter may selectively accept only a needed frequency among the applied frequencies and shield the other signals.

In addition, the SAW duplexer separates a signal received from an antenna into a transmission frequency and a reception frequency and, simultaneously, may shield noises of adjacent frequencies like the SAW filter.

Furthermore, as shown in FIG. 1, an active device 22, a passive device 24 and the like may be further installed on the substrate 20, in addition to the SAW devices 20 such as the SAW filter and the SAW duplexer.

A component such as a low noise amplifier (LNA), a switch, a power amplifier (PA) or the like can be installed as an example of the active device 22, and such an active device 22 can be installed on the substrate 10 using a conductive bump 23 or the like provided on the bottom surface of the active device 22.

A component such as a resistor, an inductor, a capacitor or the like can be installed as an example of the passive device 24.

As described above, the molding layer 30 provided with a groove 31 at both ends is formed on the substrate 10 on which the SAW device 20, the active device 22 and the passive device 24 are installed, and the groove 31 covers the SAW device 20, the active device 22 and the passive device 24 and exposes a portion of the top surface of the top ground pattern 11 provided at both upper ends of the substrate 10.

The molding layer 30 may protect the SAW device 20, the active device 22, the passive device 24 and the like installed on the substrate 10, and this can be accomplished by liquid epoxy, an epoxy molding compound (EMC) or the like.

In addition, in the high frequency module having a surface acoustic wave device according to the first embodiment of the present invention, an electromagnetic wave shield layer 40 is formed on the surface of the molding layer 30 including the inside of the grooves 31 provided at both ends of the molding layer 30 to expose the top surface of the top ground pattern 11.

The electromagnetic wave shield layer 40 is for protecting electro magnetic interference (EMI) effects of the SAW device 20 and may be formed of a metal, e.g., a material including at least any one of Ag and Cu.

At this point, the electromagnetic wave shield layer 40 may be formed in at least any one of methods including a plating method, a spray method and a sputter method.

A plurality of external electrodes 14 is formed on the bottom surface of the substrate.

According to the first embodiment of the present invention described above, the electromagnetic wave shield layer 40 is formed to cover the surface of the molding layer 30 and the top surface of the top ground pattern 11 exposed to the groove 31, and thus the electromagnetic wave shield layer 40 may directly connect to the top ground pattern 11.

As described above, according to the first embodiment of the present invention, since the top ground pattern 11 provided on the substrate 10 is directly connected to the electromagnetic wave shield layer 40, inflow of an external signal into the high frequency module and outflow of an internal signal out of the high frequency module can be efficiently suppressed.

Accordingly, according to the first embodiment of the present invention, a high frequency module having a surface acoustic wave device of superior electromagnetic wave shield performance can be provided, and it can be applied to a terminal having a GPS function which receives a weak electric field.

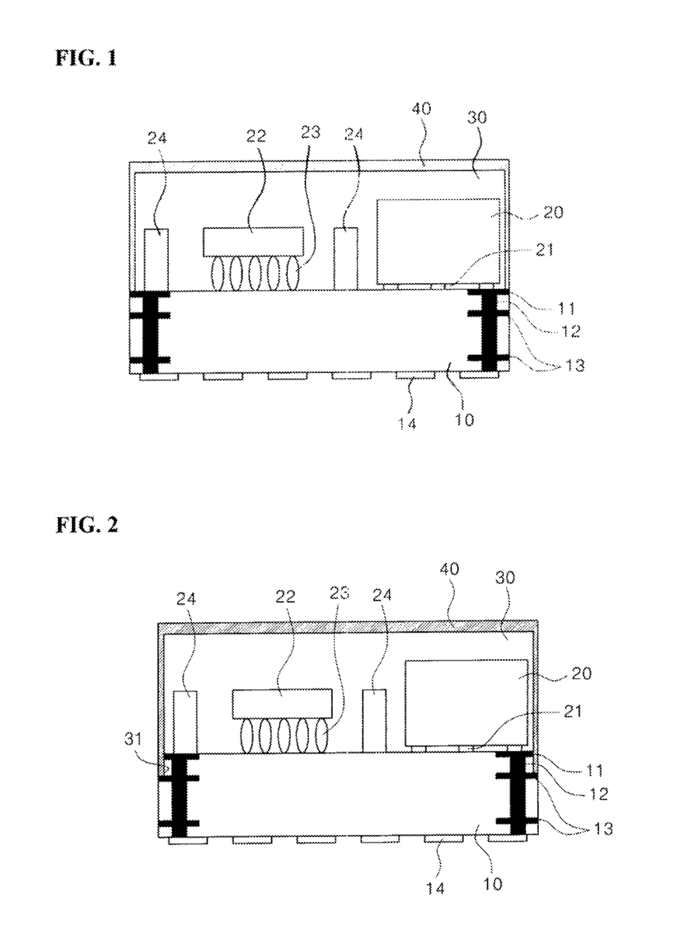

Next, a high frequency module having a surface acoustic wave device according to a second embodiment of the present invention will be described in detail with reference to FIG. 2.

FIG. 2 is a cross-sectional view showing the structure of a high frequency module having a surface acoustic wave device according to a second embodiment of the present invention.

As shown in FIG. 2, the high frequency module having a surface acoustic wave device according to the second embodiment of the present invention has a configuration that is almost the same as that of the high frequency module according to the first embodiment. However, the groove 31 is formed to be extended downward into the substrate 10 and further exposes the top surface of the inner ground pattern 13. Accordingly, the second embodiment is different from the first embodiment only in that the electromagnetic wave shield layer 40 is formed to cover the surface of the molding layer 30 including the inside of the groove 31 formed to be extended into the substrate 10.

In the high frequency module having a surface acoustic wave device according to the second embodiment of the present invention, since one side surface of the top ground pattern 11 and the top surface of the inner ground pattern 13 are exposed by the groove 31 formed to be extended downward into the substrate 10, the electromagnetic wave shield layer 40 may directly connect to the exposed surfaces of the top ground pattern 11 and the inner ground pattern 13.

Accordingly, the high frequency module having a surface acoustic wave device according to the second embodiment of the present invention may obtain actions and effects the same as those of the first embodiment, and since the electromagnetic wave shield layer 40 is directly connected to the inner ground pattern 13 as well as the top ground pattern 11, a high frequency module of further superior shield performance can be implemented.

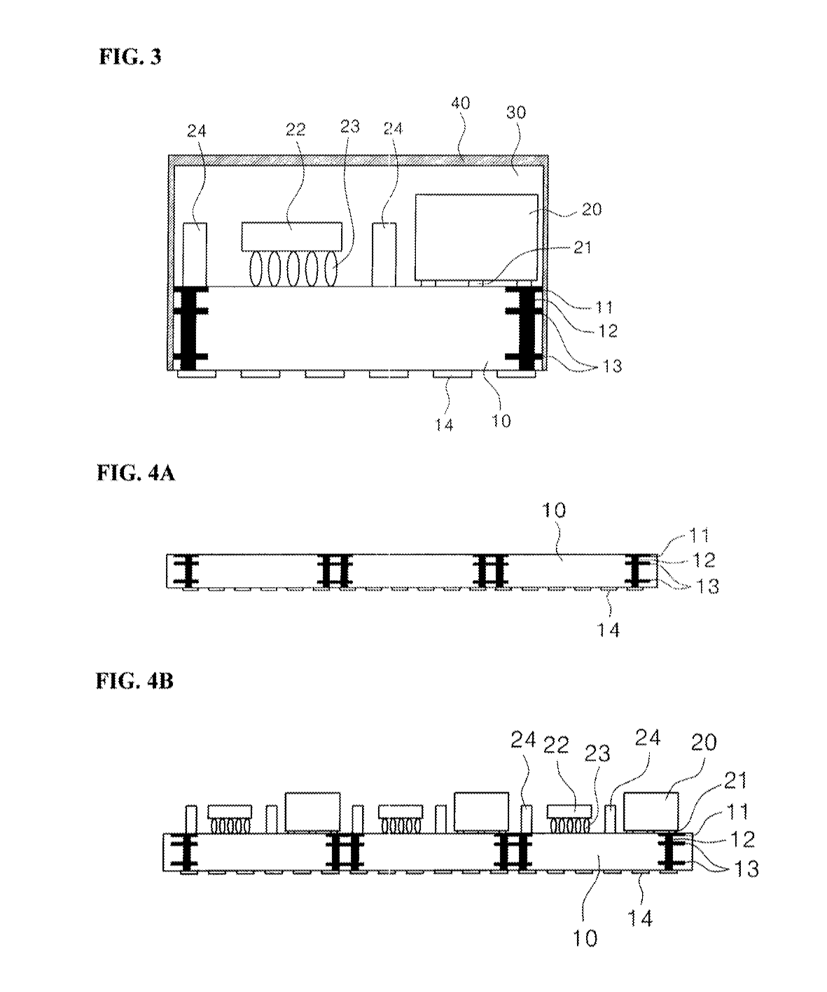

Next, a high frequency module having a surface acoustic wave device according to a third embodiment of the present invention will be described in detail with reference to FIG. 3.

FIG. 3 is a cross-sectional view showing the structure of a high frequency module having a surface acoustic wave device according to a third embodiment of the present invention.

As shown in FIG. 3, the high frequency module having a surface acoustic wave device according to the third embodiment of the present invention has a configuration that is almost the same as that of the high frequency module according to the first embodiment. However, the groove 31 is formed to be extended downward as far as the bottom surface of the substrate 10 and further exposes both side surfaces of the substrate 10 including the inner ground pattern 13. Accordingly, the third embodiment is different from the first embodiment only in that the electromagnetic wave shield layer 40 is formed to cover the surface of the molding layer 30 including the both side surfaces of the substrate 10.

In the high frequency module having a surface acoustic wave device according to the third embodiment of the present invention, since the top ground pattern 11 and one side surface of the inner ground pattern 13 are exposed by the groove 31 formed to be extended downward as far as the bottom surface of the substrate 10, the electromagnetic wave shield layer 40 may directly connect to the exposed surfaces of the top ground pattern 11 and the inner ground pattern 13.

Accordingly, the high frequency module having a surface acoustic wave device according to the third embodiment of the present invention may obtain actions and effects the same as those of the first embodiment, and since the electromagnetic wave shield layer 40 is also formed at both side surfaces of the substrate 10 and shields even noise signals generated from the side surfaces of the substrate 10, a high frequency module of further superior shield performance can be implemented.

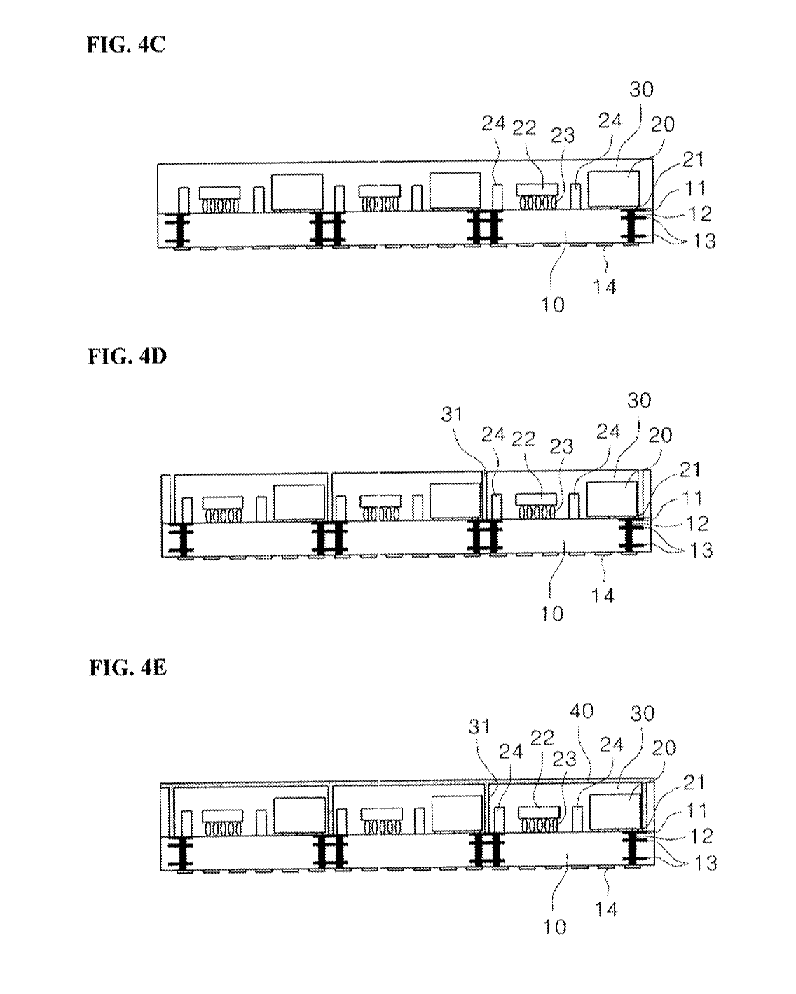

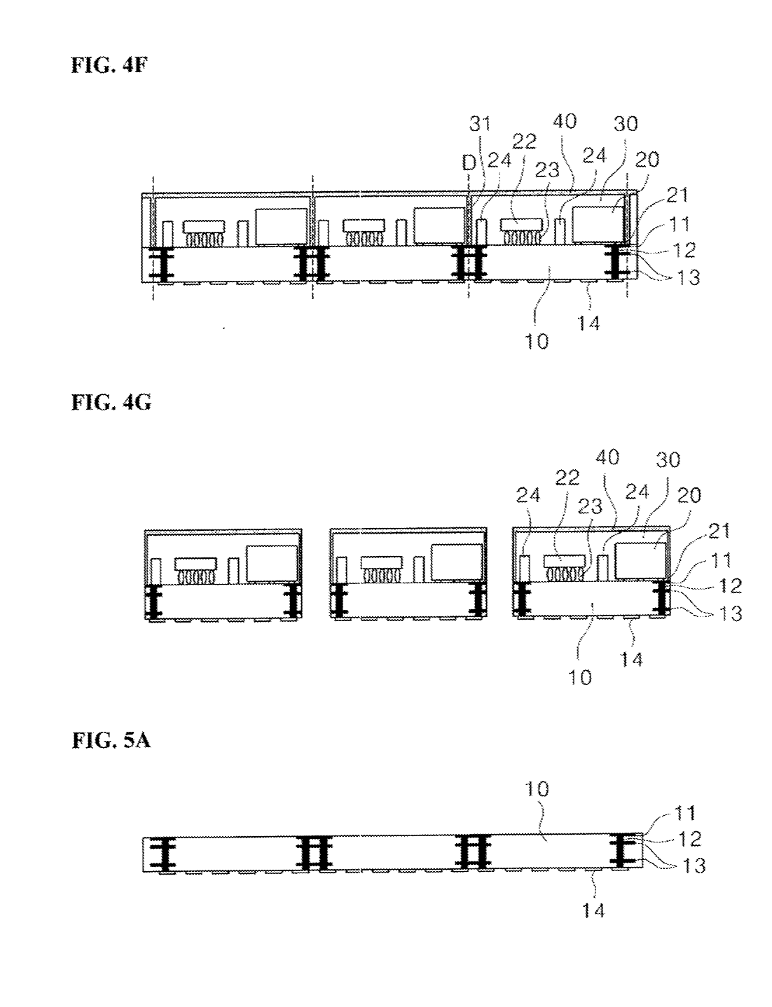

Hereinafter, a method of manufacturing a high frequency module having a surface acoustic wave device according to a first embodiment of the present invention will be described in detail with reference to FIGS. 4a to 4g.

FIGS. 4A to 4G are cross-sectional views sequentially illustrating a method of manufacturing a high frequency module having a surface acoustic wave device according to a first embodiment of the present invention.

First, a substrate 10 is prepared as shown in FIG. 4A. The substrate 10 may be formed of a ceramic substrate or a PCB substrate.

A plurality of top ground patterns 11 whose top surface is exposed to outside is provided on the top of the substrate 10, and a plurality of inner ground patterns 13 electrically connected to the top ground pattern 11 through a via electrode 12 formed to pass through a portion of the substrate 10 is provided inside the substrate 10.

That is, the too ground pattern 11 and the inner ground pattern 13 are provided in different layers, and they are electrically connected to each other through the via electrode 12 formed to pass through a portion of the substrate 10.

After the substrate 10 provided with the top and inner ground patterns 11 and 13 and the via electrode 12 is prepared, a plurality of external electrodes 14 is formed on the bottom surface of the substrate 10.

Next, as shown in FIG. 4B, one or more SAW devices 20 are installed on the top surface of the substrate 10 with the intervention of an electrode pattern 21.

The SAW device 20 may include at least any one of a SAW filter and a SAW duplexer.

Next, a plurality of active devices 22 and a plurality of passive devices 24 are installed on the substrate 10. As described above, components such as a LNA, a switch, a PA and the like can be installed as the active device 22, and components such as a resistor, an inductor, a capacitor and the like can be installed as the passive device 24.

Although the active devices 22 and the passive devices can be installed after the SAW device 20 is installed, they can be installed before the SAW device 20 is installed.

Next, as shown in FIG. 4C, a molding layer 30 is formed on the substrate 10 on which the SAW device 20, the active devices 22 and the passive devices 24 are installed, to cover the SAW device 20, the active devices 22 and the passive devices 24.

The molding layer 30 may protect the SAW device 20, the active devices 22, the passive devices 24 and the like, and the molding layer 30 may be formed of liquid epoxy, an EMC or the like.

Next, as shown in FIG. 4D, a groove 31 which exposes a portion of the top surface of the top ground pattern 11 is formed by removing a portion of the molding layer 30 between the SAW devices 20.

Next, as shown in FIG. 4E, an electromagnetic wave shield layer 40 is formed on the surface of the molding layer 30 including the inside of the groove 31.

The electromagnetic wave shield layer 40 is for protecting electro magnetic interference (EMI) effects of the SAW device 20 and may be formed of a metal, e.g., a material including at least any one of Ag and Cu.

At this point, the electromagnetic wave shield layer 40 may be formed in at least any one of methods including a plating method, a spray method and a sputter method.

According to the method of manufacturing a high frequency module having a surface acoustic wave device according to the first embodiment of the present invention, the electromagnetic wave shield layer 40 is formed on the molding layer 30 including the groove 31 which exposes the top ground pattern 11, and thus the electromagnetic wave shield layer 40 may directly connect to the top ground pattern 11.

Therefore, according to the method of manufacturing a high frequency module having a surface acoustic wave device according to the first embodiment of the present invention, since inflow and outflow of noise signals are effectively prevented, a high frequency module having superior electromagnetic wave shield performance can be provided.

Next, the resulting high frequency module is cut along a dicing line D as shown in FIG. 4F and divided into individual high frequency module units as shown in FIG. 4G.

That is, a plurality of high frequency modules can be obtained by cutting the electromagnetic wave shield layer 40 and the substrate 10 using a line passing through the center of the groove 31 as a dicing line C.

According to the method of manufacturing a high frequency module having a surface acoustic wave device according to the first embodiment of the present invention described above, a plurality of high frequency modules can be simultaneously obtained through a cutting process, and thus it is advantageous for mass production.

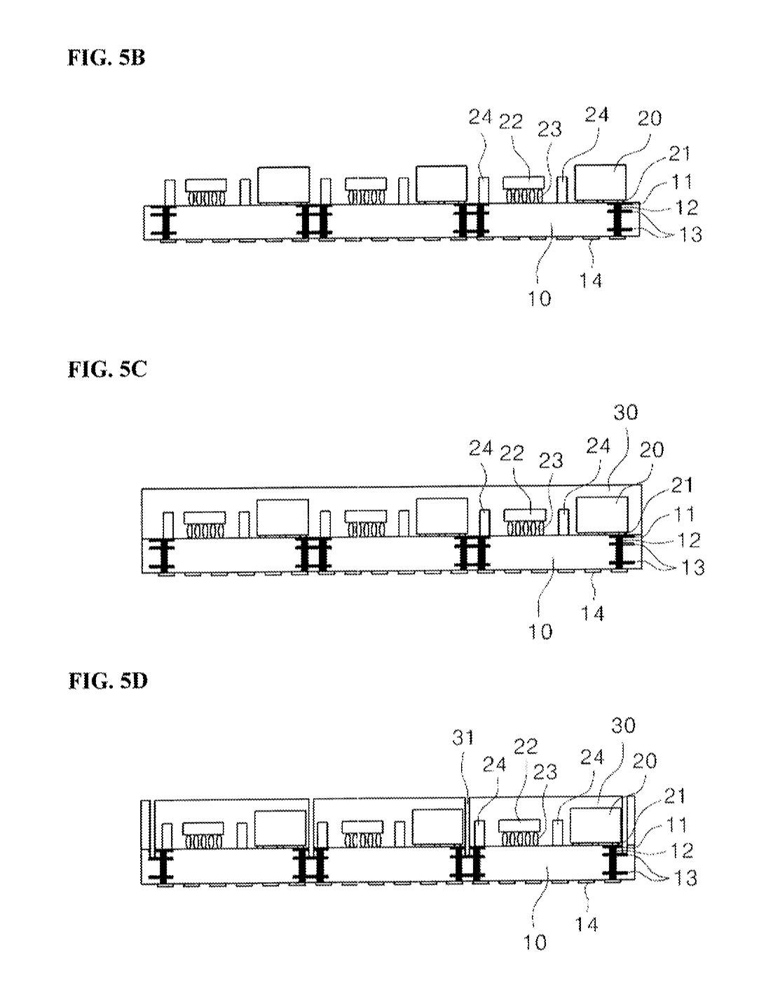

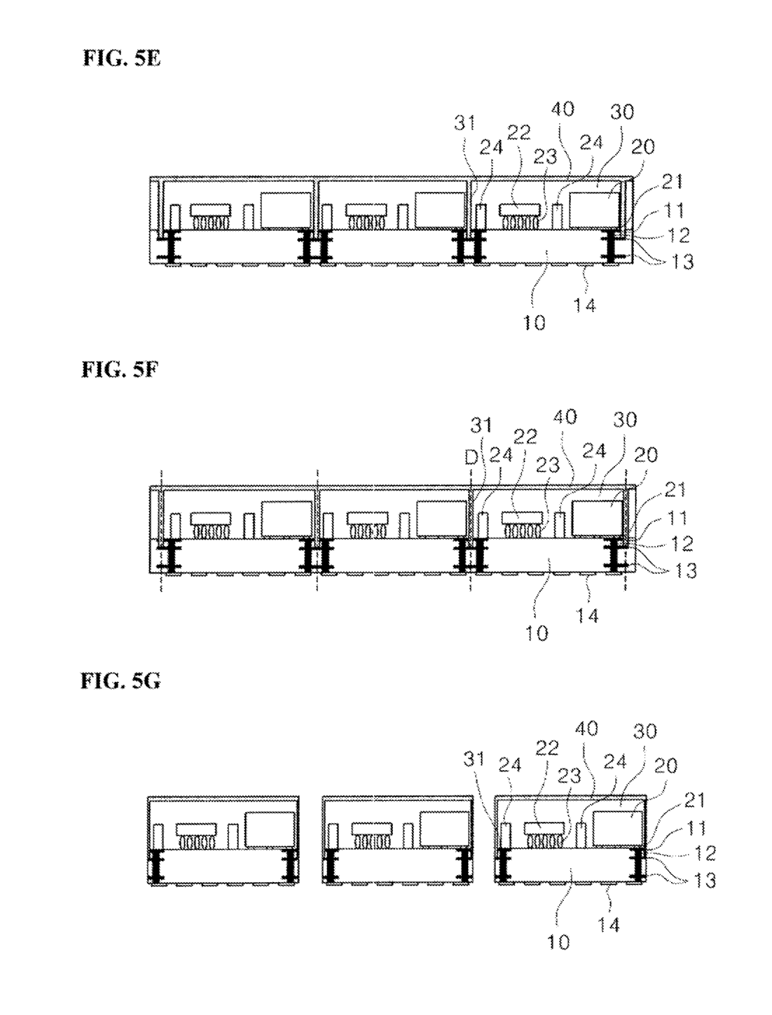

Next, a method of manufacturing a high frequency module having a surface acoustic wave device according to a second embodiment of the present invention will be described in detail with reference to FIGS. 5A to 5G.

FIGS. 5A to 5G are cross-sectional views sequentially illustrating a method of manufacturing a high frequency module having a surface acoustic wave device according to a second embodiment of the present invention.

First, a substrate 10 is prepared as shown in FIG. 5A. A plurality of top ground patterns 11 is provided on the top of the substrate 10, and a plurality of inner ground patterns 13 electrically connected to the top ground pattern 11 through a via electrode 12 formed to pass through a portion of the substrate 10 is provided inside the substrate 10.

That is, the top ground pattern 11 and the inner ground pattern 13 are provided in different layers, and they are electrically connected to each other through the via electrode 12 formed to pass through a portion of the substrate 10.

After the substrate 10 provided with the top and inner ground patterns 11 and 13 and the via electrode 12 is prepared, a plurality of external electrodes 14 is formed on the bottom surface of the substrate 10.

Next, as shown in FIG. 5B, one or more SAW devices 20 are installed on the top surface of the substrate 10 with the intervention of an electrode pattern 21.

The SAW device 20 may include at least any one of a SAW filter and a SAW duplexer.

Next, a plurality of active devices 22 and a plurality of passive devices 24 are installed on the substrate 10. As described above, components such as a LNA, a switch, a PA and the like can be installed as the active device 22, and components such as a resistor, an inductor, a capacitor and the like can be installed as the passive device 24.

Although the active devices 22 and the passive devices can be installed after the SAW device 20 is installed, they can be installed before the SAW device 20 is installed.

Next, as shown in FIG. 5C, a molding layer 30 is formed on the substrate 10 on which the SAW device 20, the active devices 22 and the passive devices 24 are installed, to cover the SAW device 20, the active devices 22 and the passive devices 24.

The molding layer 30 may be formed of liquid epoxy, an EMC or the like.

Next, as shown in FIG. 5D, a groove 31 which exposes a portion of the top ground pattern 11 and the inner ground pattern 13 is formed by removing a portion of the molding layer 30 and the substrate 10 between the SAW devices 20.

Here, in the second embodiment of the present invention, when the groove 31 is formed, a part in thickness of the substrate 10 is removed together with the molding layer 30 so that the groove 31 may be formed to be extended as far as the molding layer 30 and the inside of the substrate 10 under the molding layer 30, and thus the groove 31 formed inside the substrate 10 exposes one side surface of the top ground pattern 11 and the top surface of the inner ground pattern 13.

Next, as shown in FIG. 5E, an electromagnetic wave shield layer 40 is formed on the surface of the molding layer 30 including the inside of the groove 31.

The electromagnetic wave shield layer 40 may be formed of a material including at least any one of Ag and Cu in at least any one of methods including a plating method, a spray method and a sputter method.

According to the method of manufacturing a high frequency module having a surface acoustic wave device according to the second embodiment of the present invention, the electromagnetic wave shield layer 40 may directly connect to the top ground pattern 11 and the inner ground pattern 13.

Therefore, according to the method of manufacturing a high frequency module having a surface acoustic wave device according to the second embodiment of the present invention, actions and effects the same as those of the first embodiment can be obtained, and since the electromagnetic wave shield layer 40 is directly connected to the inner ground pattern 13 as well as the top ground pattern 11, a high frequency module of further superior shield performance can be implemented.

Next, the resulting high frequency module is cut along a dicing line D as shown in FIG. 5F and divided into individual high frequency module units as shown in FIG. 5G.

That is, a plurality of high frequency modules can be obtained by cutting the electromagnetic wave shield layer 40 and the substrate 10 using a line passing through the center of the groove 31 as a dicing line D.

According to the method of manufacturing a high frequency module having a surface acoustic wave device according to the second embodiment of the present invention described above, a plurality of high frequency modules can be simultaneously obtained through a process of cutting the high frequency module along the dicing line in a manner that is the same as that of the first embodiment, and thus it is advantageous for mass production.

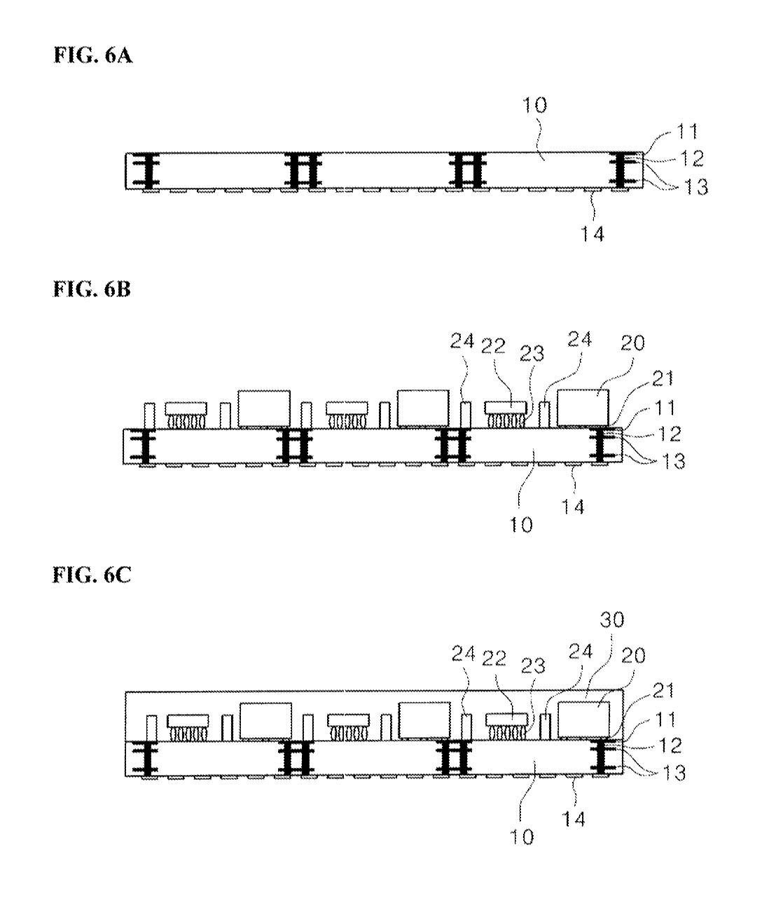

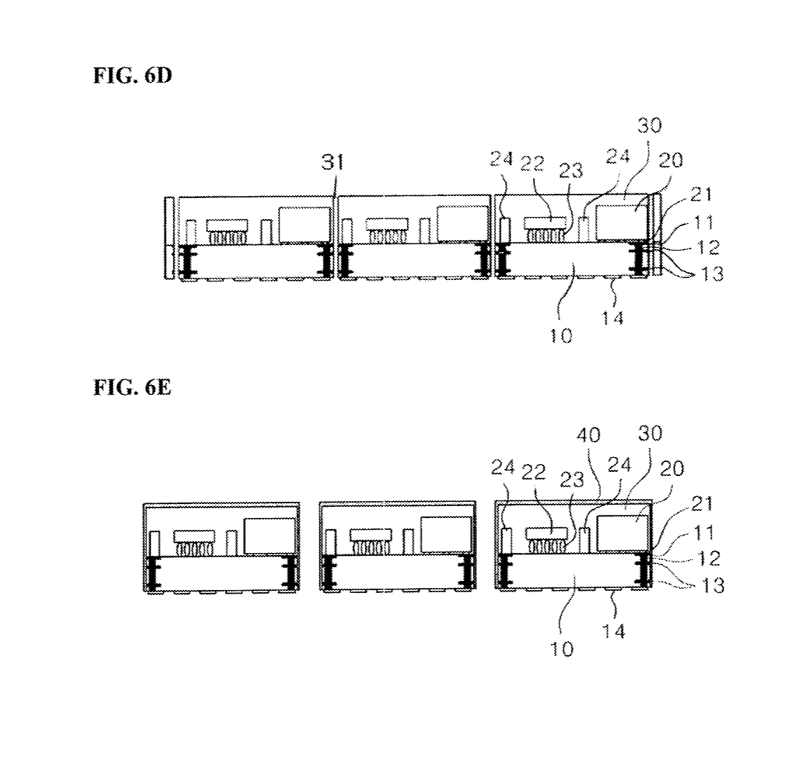

Next, a method of manufacturing a high frequency module having a surface acoustic wave device according to a third embodiment of the present invention will be described in detail with reference to FIGS. 6A to 6E.

FIGS. 6A to 6E are cross-sectional views sequentially illustrating a method of manufacturing a high frequency module having a surface acoustic wave device according to a third embodiment of the present invention.

First, a substrate 10 is prepared as shown in FIG. 6A. A plurality of top ground patterns 11 is provided on the top of the substrate 10, and a plurality of inner ground patterns 13 electrically connected to the top ground pattern 11 through a via electrode 12 formed to pass through a portion of the substrate 10 is provided inside the substrate 10.

That is, the top ground pattern 11 and the inner ground pattern 13 are provided in different layers, and they are electrically connected to each other through the via electrode 12 formed to pass through a portion of the substrate 10.

After the substrate 10 provided with the top and inner ground patterns 11 and 13 and the via electrode 12 is prepared, a plurality of external electrodes 14 is formed on the bottom surface of the substrate 10.

Next, as shown in FIG. 6B, one or more SAW devices 20 are installed on the top surface of the substrate 10 with the intervention of an electrode pattern 21.

The SAW device 20 may include at least any one of a SAW filter and a SAW duplexer.

Next, a plurality of active devices 22 and a plurality of passive devices 24 are installed on the substrate 10. As described above, components such as a LNA, a switch, a PA and the like can be installed as the active device 22, and components such as a resistor, an inductor, a capacitor and the like can be installed as the passive device 24.

Although the active devices 22 and the passive devices can be installed after the SAW device 20 is installed, they can be installed before the SAW device 20 is installed.

Next, as shown in FIG. 6C, a molding layer 30 is formed on the substrate 10 on which the SAW device 20, the active devices 22 and the passive devices 24 are installed, to cover the SAW device 20, the active devices 22 and the passive devices 24.

The molding layer 30 may be formed of liquid epoxy, an EMC or the like.

Next, as shown in FIG. 6D, a groove 31 which exposes one end of the top ground pattern 11 and the inner ground pattern 13 while passing through both the molding layer 30 and the substrate 10 is formed by removing a portion of the molding layer 30 and the substrate 10 between the SAW devices 20.

Here, in the third embodiment of the present invention, when the groove 31 is formed, the entire thickness of the substrate 10 is removed together with the molding layer 30 so that the groove 31 may pass through the molding layer 30 and the substrate 10 under the molding layer 30, and thus the groove 31 exposes one end of the top and inner ground patterns 11 and 13.

Next, as shown in FIG. 6E, after an electromagnetic wave shield layer 40 is formed on the surface of the molding layer 30 including the inside of the groove 31, the resulting high frequency module is cut into individual high frequency module units using a line passing through the center of the groove 31 as a dicing line.

The electromagnetic wave shield layer 40 may be formed of a material including at least any one of Ag and Cu in at least any one of methods including a plating method, a spray method and a sputter method.

According to the method of manufacturing a high frequency module having a surface acoustic wave device according to the third embodiment of the present invention, the electromagnetic wave shield layer 40 may directly connect to the top ground pattern 11 and the inner ground pattern 13.

Therefore, according to the method of manufacturing a high frequency module having a surface acoustic wave device according to the third embodiment of the present invention, actions and effects the same as those of the second embodiment can be obtained, and since the electromagnetic wave shield layer 40 is formed to cover the entire side surface of the substrate 10, even noise signals generated from the side surface of the substrate 10 are shielded, and thus a high frequency module of further superior shield performance can be implemented.

As described above, according to the high frequency module having a surface acoustic wave device and the method of manufacturing the same, the ground pattern provided on the substrate is electrically connected to the electromagnetic wave shield layer formed on the molding layer, and thus inflow and outflow of noise signals can be effectively prevented.

Accordingly, the present invention is effective in that a high frequency module having a surface acoustic wave device of superior electromagnetic wave shield performance can be provided.

While the present invention has been described with reference to the particular illustrative embodiments, it is not to be restricted by the embodiments but only by the appended claims. It is to be appreciated that those skilled in the art can change or modify the embodiments without departing from the scope and spirit of the present invention.

What is claimed is:

1. A high frequency module having a surface acoustic wave device, the module comprising:
a substrate provided with a top ground pattern at both upper ends and provided with, inside thereof, an inner ground pattern electrically connected to the top ground pattern through a via electrode;
at least one SAW device installed on the substrate;
a molding layer formed on the substrate to cover the SAW device and provided with a groove at both ends to expose the top ground pattern; and
an electromagnetic wave shield layer formed to cover a surface of the molding layer including an inside of the groove.

2. The module according to claim 1, wherein the groove is formed to be extended downward into the substrate and exposes the top ground pattern.

3. The module according to claim 1, wherein the groove is formed to be extended to a bottom surface of the substrate and exposes both side surfaces of the substrate including the inner ground pattern.

4. The module according to claim 1, wherein the SAW device includes at least any one of a SAW filter and a SAW duplexer.

5. The module according to claim 1, wherein the electromagnetic wave shield layer is formed of a material including at least any one of Ag and Cu.

6. The module according to claim 1, wherein the electromagnetic wave shield layer is formed in at least any one of methods including a plating method, a spray method and a sputter method.

7. A method of manufacturing a high frequency module having a surface acoustic wave device, the method comprising the steps of:
preparing a substrate provided with a top ground pattern at both upper ends and provided with, inside thereof, an inner ground pattern electrically connected to the top ground pattern through a via electrode;
installing one or more SAW devices on a top surface of the substrate;
forming a molding layer on the substrate to cover the SAW device;
forming a groove by removing a portion of the molding layer between the SAW devices to expose the top ground pattern;
forming an electromagnetic wave shield layer on a surface of the molding layer including an inside of the groove; and
dividing the high frequency module formed with the electromagnetic wave shield layer into individual high frequency module units by cutting the high frequency module along a dicing line.

8. A method of manufacturing a high frequency module having a surface acoustic wave device, the method comprising the steps of:
preparing a substrate provided with a top ground pattern at both upper ends and provided with, inside thereof, an inner ground pattern electrically connected to the top ground pattern through a via electrode;
installing one or more SAW devices on a top surface of the substrate;
forming a molding layer on the substrate to cover the SAW device;
forming a groove by removing a portion of the molding layer and the substrate between the SAW devices to expose the top ground pattern and the inner ground pattern;
forming an electromagnetic wave shield layer on a surface of the molding layer including an inside of the groove; and
dividing the high frequency module formed with the electromagnetic wave shield layer into individual high frequency module units by cutting the high frequency module along a dicing line.

9. The method according to claim 8, wherein in the step of forming a groove by removing a portion of the molding layer and the substrate between the SAW devices to expose the top ground pattern and the inner ground pattern, the substrate is removed as much as some of thickness or entire thickness.
